(19) United States
(12) Patent Application Publication
(10) Pub. No.: US 2025/0384923 A1
(43) Pub. Date: Dec. 18, 2025

(54) MEMORY CIRCUITS WITH WORD LINE ASSISTANCE CIRCUITS AND METHODS FOR OPERATING THE SAME

(71) Applicant: Taiwan Semiconductor Manufacturing Company, Ltd., Hsinchu (TW)

(72) Inventors: Masayuki Ichikawa, Hsinchu City (TW); Makato Yabuuchi, Hsinchu City (TW)

(73) Assignee: Taiwan Semiconductor Manufacturing Company, Ltd., Hsinchu (TW)

(21) Appl. No.: 18/923,010

(22) Filed: Oct. 22, 2024

Related U.S. Application Data
(60) Provisional application No. 63/659,492, filed on Jun. 13, 2024.

(51) Int. Cl. G11C 11/419; G11C 5/06; G11C 11/418

(52) U.S. Cl. CPC G11C 11/419; G11C 5/063; G11C 11/418

(57) ABSTRACT

A memory circuit includes a memory array comprising first memory cells, each of the first memory cells configured to store a data bit; a tracking column comprising at least a second memory cell and a third memory cell, wherein the second memory cell is coupled to a first tracking bit line, a second tracking bit line, and a tracking word line, and the third memory cell is coupled to the first tracking bit line; and a word line assistance circuit coupled to the memory array and the tracking column. The word line assistance circuit can receive a control signal present on a control line coupled to the third memory cell; and in response to a transition of the control signal, increase a voltage level of an operation voltage applied to a word line corresponding to an asserted one of the first memory cells.

### CROSS-REFERENCE TO RELATED APPLICATION

This application claims priority to and the benefit of U.S. Provisional Application No. 63/659,492, filed Jun. 13, 2024, entitled “WORD-LINE OVERDRIVE CIRCUIT,” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory circuit, in accordance with some embodiments.

FIG. 2 illustrates a circuit diagram of one implementation of the memory circuit of FIG. 1, in accordance with some embodiments.

FIG. 3 illustrates waveforms of various signals when operating the memory circuit implemented according to the circuit diagram of FIG. 2, in accordance with some embodiments.

FIG. 4 illustrates an example circuit diagram of a tracking column of the memory circuit of FIG. 1, in accordance with some embodiments.

FIG. 5 illustrates another example circuit diagram of a tracking column of the memory circuit of FIG. 1, in accordance with some embodiments.

FIG. 6 illustrates circuit diagrams of circuit components of the memory circuit of FIG. 1, in accordance with some embodiments.

FIG. 7 illustrates waveforms of various signals when operating the memory circuit implemented according to the circuit diagram of FIG. 6, in accordance with some embodiments.

FIG. 8 illustrates a circuit diagram of another implementation of the memory circuit of FIG. 1, in accordance with some embodiments.

FIG. 9 illustrates circuit diagrams of circuit components of the memory circuit implemented according to the circuit diagram of FIG. 8, in accordance with some embodiments.

FIG. 10 illustrates waveforms of various signals when operating the memory circuit implemented according to the circuit diagram of FIG. 8, in accordance with some embodiments.

FIG. 11 illustrates a flow chart of an example method for operating a memory circuit, in accordance with some embodiments.

FIG. 12 illustrates a flow chart of another example method for operating a memory circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Many modern electronic devices and systems include substantial computational capability for controlling and managing a wide range of functions and useful applications. The computational power of these modern devices and systems is typically provided by one or more processor cores. These processor cores operate as a digital computer, in general retrieving executable instructions from memory, performing arithmetic and logical operations on digital data retrieved from memory, and storing the results of those operations in memory. Other input and output functions for acquiring and outputting the data processed by the processor cores are performed as appropriate. Considering the large amount of digital data often involved in performing the complex functions of these modern devices, significant solid-state memory capacity is generally implemented in the electronic circuitry for these systems.

Static random access memory (SRAM) has become the memory technology of choice for much of the solid-state data storage requirements in these modern power-conscious electronic systems. SRAM is a type of volatile semiconductor memory that stores data bits using bi-stable circuitry that does not need refreshing. An SRAM device typically includes one or more memory arrays, wherein each array includes a plurality of SRAM cells. An SRAM cell is typically referred to as a memory cell (or a bit cell) as it stores one bit of information, represented by the logic state of two cross coupled inverters. Each memory array includes multiple bit cells arranged in rows and columns. Each bit cell in a memory array typically includes connections to a power supply voltage and to a reference voltage. Logic signals on bit lines control reading from and writing to a bit cell, with a word line controlling connections of the bit lines to the inverters, which otherwise float. A word line may be coupled to plural bit cells along a row of a memory array, with different word lines provided for different rows.

With the rapid scaling trend, the existing SRAM devices generally face ever increasingly demanding requirement of reducing power consumption and increasing speed. For example, in system-on-chip (SOC) applications, to reduce power consumption, when in a sleep mode or a low-power mode, the operation voltage of logic circuits can be reduced or turned off to save power. However, in such SOC applications, the processor (e.g., a central computing unit (CPU), a mobile accelerated processing unit (APU), etc.) may remain operating in the sleep mode and need to access level-1 (L1) cache memories (e.g., an L1 data cache memory, an L1 instruction cache memory). Thus, the operation voltage of SRAM devices used in the L1 cache SRAM devices may affect the operation voltage of the processor and the overall power consumption. However, reduction in the operation voltage of the SRAM devices may result in an SRAM cell stability concern such as, for example, a degraded write margin.

In this regard, a word line (WL) assistance circuit has been proposed. Generally, the existing WL assistance circuit is coupled to one or more word lines of a memory array, and can boost a voltage present on an asserted one of the word lines (WL voltage). For example, the WL voltage may be first provided as being equal to a supply voltage (VDD), and the WL voltage may be boosted to a higher voltage level with a corresponding charger or booster circuit being activated. However, a timing regarding when the booster circuit is activated is not well defined according to actual operation of the corresponding memory array. For example, if the booster circuit is activated too early, data corruption on the memory array occurs. In another example, if the booster circuit is activated too late, performance of the memory array degrades. Thus, the existing SRAM devices with a WL assistance circuit have not been entirely satisfactory in certain aspects.

The present disclosure provides various embodiments of a memory circuit including a memory array and a word-line assistance circuit. In various embodiments, the WL assistance circuit can be accurately activated based on a tracking signal emulating the propagation delay present in the memory array. For example, the memory array can include a plural number of nominal memory cells, and the memory circuit can further include a tracking column physically and operatively coupled to the memory array. Such a tracking column can be integrated into the memory array. The tracking column can include various types of tracking cells. For example, a first tracking cell can emulate the propagation (or signal routing) delay on a nominal bit line of the memory array as a tracking signal present on a tracking bit line, a second tracking cell can emulate a loading of the nominal bit line, and a third tracking cell can transition a control signal in response to detecting a transition of the tracking signal. The memory circuit, as disclose herein, can utilize the transition of that control signal to activate the WL assistance circuit, which is configured to boost a WL voltage. In various embodiments of the present disclosure, the third tracking cell, which essentially functions as an inverter, is coupled between the tracking bit line and a control line presenting the control signal. As such, the WL assistance circuit is not activated until the tracking signal (present on the tracking bit line) changes. In this way, boosting of the WL voltage can be accurately controlled. For example, the WL voltage is boosted after a large enough voltage difference between a nominal bit line BL and nominal bit line bar BLB is set. Accordingly, the disclosed memory circuit can be immune from data corruption, while being operative under high speed.

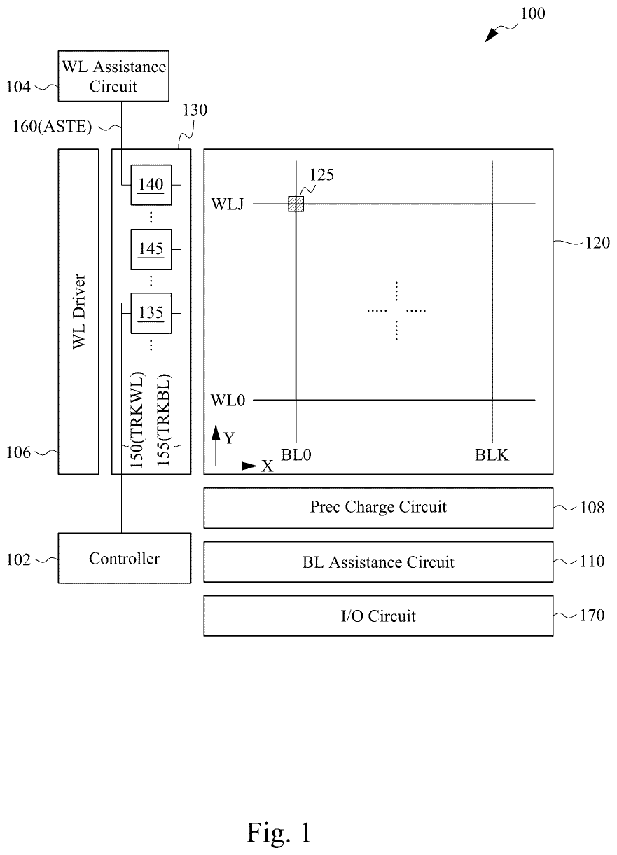

FIG. 1 illustrates a block diagram of a memory device (or circuit) 100, in accordance with various embodiments. As a brief overview, the memory circuit 100, as disclosed herein, can include a WL assistance circuit that can be accurately activated based on a tracking signal, and upon being activated, the WL assistance circuit can boost a voltage level present on a nominal word line WL. The memory circuit 100 shown in FIG. 1 has been simplified for illustrative purposes, and thus, it should be appreciated that the memory circuit 100 can include any of various other components while remaining within the scope of the present disclosure.

As shown, the memory circuit 100 includes a memory controller 102, a WL assistance circuit 104, a WL driver 106, a pre-charge circuit 108, an optional BL assistance circuit 110, and a memory array 120. In various embodiments, the memory array 120 may include a plurality of storage circuits or memory cells 125 arranged as one or more two-dimensional or three-dimensional arrays. Each memory cell 125 may be coupled to one or more corresponding word lines (WLs) and one or more corresponding bit line (BLs). The memory cell 125 configured to store a data bit, the coupled word line WL, and the coupled bit line BL are sometimes referred to as a nominal memory cell, a nominal word line WL, and a nominal bit lien BL, respectively. The memory controller 102 can write data to or read data from the nominal memory cells 125 according to electrical signals present on corresponding nominal word lines WL and nominal bit lines BL. In other embodiments, the memory circuit 100 includes more, fewer, or different components than shown in FIG. 1.

The memory array 120 is a hardware component that stores data bits. The memory array 120 includes nominal word lines WL₀ . . . WL_{J}, each extending in a first direction (e.g., the X-direction) and nominal bit lines BL₀ . . . BL_{K}, each extending in a second direction (e.g., the Y-direction). In some embodiments, the memory array 120 may be referred to as having a number of columns and a number of rows, where each of the columns corresponds to a respective one of the nominal bit lines BLs and each of the rows corresponds to a respective one of the nominal word lines WLs. In the example of FIG. 1, the memory array 120 can include K columns and J rows of the nominal memory cells 125. The nominal word lines WL and the nominal bit lines BL may be conductive metals or conductive rails, in some embodiments. Each nominal memory cell 125 is coupled to at least one corresponding nominal word line WL and at least one corresponding nominal bit line BL, and can be operated according to voltages or currents through the corresponding nominal word line WL and the corresponding nominal bit line BL.

In some embodiments, each nominal bit line includes nominal bit lines, BL and BLB, coupled to one or more nominal memory cells 125 disposed along the second direction (e.g., the Y-direction). The nominal bit lines, BL and BLB, may receive and/or provide differential signals. Each nominal memory cell 125 may include a volatile memory, a non-volatile memory, or a combination of them. In some embodiments, each nominal memory cell 125 is embodied as a static random access memory (SRAM) cell or other type of memory cell. In some embodiments, the memory array 120 can include additional lines (e.g., select lines, reference lines, reference control lines, power rails, etc.), while remaining within the scope of the present disclosure.

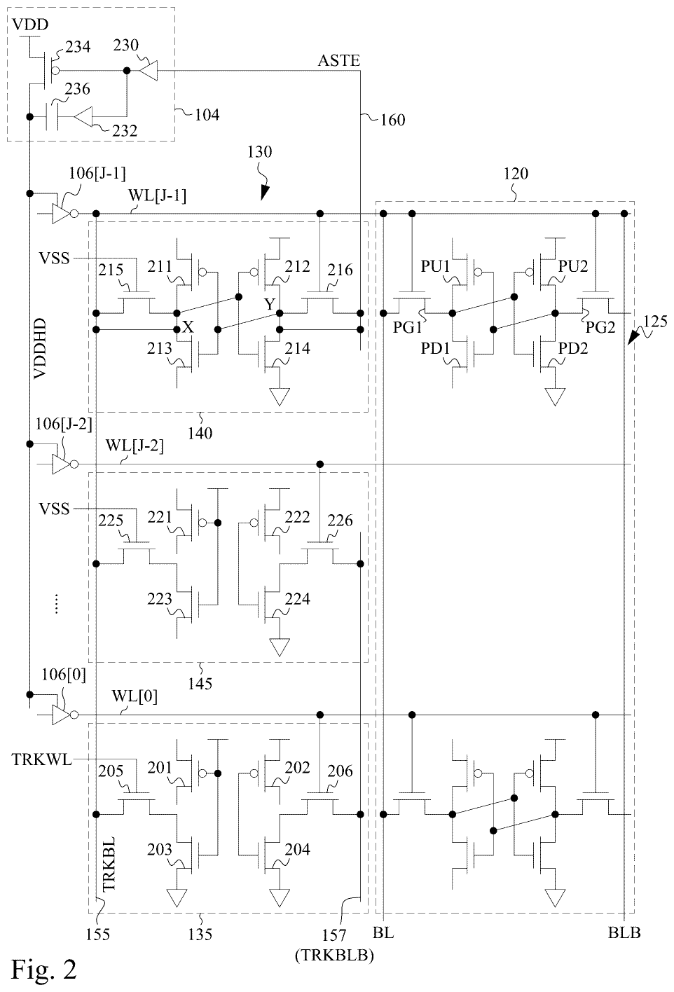

For example, the nominal memory cell 125 may be implemented as a six-transistor (6T) static random access memory (SRAM) cell that consists of six transistors. An example of the 6T SRAM cell may be better appreciated in the circuit diagram of FIG. 2. In general, the nominal memory cell 125 can include a pair of access or pass-gate transistors, PG1 and PG2, biased by (e.g., gated by) a corresponding nominal word line WL. The pass-gate transistors PG1 and PG2 provide access to cross-coupled first and second inverters, respectively. The pass-gate transistors PG1 and PG2 can pass bit line signals to internal nodes of the cross-coupled first and second inverters, when a WL signal (voltage) fed into the gate terminals of the pass-gate transistors PG1 and PG2 becomes true or the corresponding nominal word line WL is asserted. Stated another way, when a nominal word line WL is asserted, the WL signal applied on the nominal word line WL can turn on the pass-gate transistors PG1 and PG2. The first inverter includes a pull-up (e.g., PMOS) transistor PU1 and a pull-down (e.g., NMOS) transistor PD1, and the second inverter includes a pull-up (e.g., PMOS) transistor PU2 and a pull-down (e.g., NMOS) transistor PD2. The pass-gate transistors PG1 and PG2 respectively are coupled to a first nominal bit line BL (“bit line”) and to a second nominal bit line BLB (“bit line bar” or bit line complement). This configuration is generally referred to as a 6T (six-transistor) configuration.

During a standby mode, the nominal word line WL is not asserted, and thus the pass-gate transistors PG1 and PG2 disconnect the nominal memory cell 125 from the nominal bit lines, the nominal BL and BLB. The cross-coupled inverters are coupled between power supplies (e.g., VDD and VSS), and reinforce each other to maintain one of two possible logic states with a stored data bit at one of the internal nodes between the inverters (sometimes referred to as a node Q or node BL_IN) and the complement of that bit at the other node between the inverters (sometimes referred to as a node QB or node BLB_IN). During a read operation, the nominal BL and BLB are pre-charged to a high logic state (e.g., a logic 1), and the nominal WL is asserted. The stored data bit at the node Q is transferred to the nominal BL, and the data bit at the node QB is transferred to the nominal BLB. During a write operation, the value to be written is provided at the nominal BL, and the complement of that value is provided at the nominal BLB, when the nominal WL is asserted. Although the 6T SRAM cells are herein described as an example implementation of the memory cell 125, it should be understood that the memory cell 125 can be implemented as other types of memory cells, including types of memory other than SRAM and other types of SRAM configurations than 6T (e.g., eight transistor (8T) or ten transistor (10T) configurations) while remaining within the scope of the present disclosure.

In addition to the nominal memory cells 125 configured to store data bits, the memory circuit 100 may include one or more tracking columns 130 disposed next to or integrated into the memory array 120. For example, in FIG. 1, the tracking column 130 may be disposed along one of the edges of the memory array 120 that extend in parallel with the nominal bit lines, BL₀ to BL_{K}. In various embodiments of the present disclosure, the tracking column 130 can each include a number of first tracking cells 135, a number of second tracking cells 140, and optionally a number of third tracking cells 145. The first tracking cells 135 can be configured to emulate a signal routing delay on the nominal bit line BL and present the emulated signal as a tracking signal, the second tracking cells 140 can be configured to provide a control signal to activate a WL assistance circuit (e.g., 104) based on a transition of the tracking signal, and the third tracking cells 145 can be configured to emulate a loading of the nominal bit line BL, which will be discussed in further detail below. The first to third tracking cells 135, 140, and 145, may be configured in any respective numbers, while remaining within the scope of the present disclosure. In some embodiments, a total number of the first to third tracking cells, 135, 140, and 145, may be equal to the number of rows (J). As a non-limiting example, the number of first tracking cells 135 may be selected to simulate a worst-case condition in a write and/or read operation.

The tracking column 130 can further include at least one tracking word line (TRKWL) 150, at least one tracking bit line (TRKBL) 155, and at least one control line 160. In some embodiments, each of the first tracking cells 135 can be coupled to the tracking word line TRKWL 150 and tracking bit line TRKBL 155, each of the second tracking cells 140 can be coupled to the tracking bit line TRKBL 155 and control line 160, and each of the third tracking cells 145 can be coupled to the tracking bit line TRKBL 155. The tracking word line TRKWL 150, tracking bit line TRKBL 155, and control line 160 are configured to conduct respective tracking/control signals (e.g., a TRKBL signal, a TRKWL signal, an ASTE signal, etc.), which will be discussed in further detail below.

For example, the tracking word line TRKWL 150 may include a (e.g., horizontal) portion extending along the rows of the memory array 120 (not expressly shown), and the (e.g., vertical) portion shown in FIG. 1 that extends along the columns of the memory array 120. A length of the vertical portion of the tracking word line TRKWL 150 may be approximately equal to a height of the memory array (e.g., a distance from the memory controller 102 to the farthest tracking cell of the tracking column 130, according to the orientation of the memory array in FIG. 1); and a length of the horizontal portion of the tracking word line TRKWL 150 may be approximately equal to a width of the memory array 120 (e.g., a distance along any of the rows from one edge of the array to the other, according to the orientation of the memory array in FIG. 1). Accordingly, a sum of the lengths of the first and second portions of the tracking word line TRKWL 150 may be configured such that the metal routing delay for accessing a cell at the top right corner of the memory array 120 is emulated, e.g., the delay from signal entry at the bottom left, propagating horizontally and vertically, over a path distance equal to the length of a path from one corner to the diagonally opposite corner.

In general, the tracking cells (135, 140, or 145) do not function as the nominal memory cells 125 do in terms of storing data bits and supporting read/write operations. Rather, the tracking cells 135 to 145 may originally be a subset of the nominal memory cells 125 but be enlisted, or re-purposed, for timing tracking. As such, the tracking column 130, including the tracking cells 135 to 145, can be a part of the memory array 120, in some embodiments.

For example, the first tracking cells 135 are bit cells with fixed logic values configured and coupled to one another so as to respond in a predictable way when addressed by test or tracking signals. Some non-limiting implementations of the first tracking cell 135 will be discussed below. The second tracking cell 140 can essentially function as an inverter coupled between the tracking bit line TRKBL 155 and control line 160. In response to detecting a transition edge on the tracking bit line TRKBL 155 (e.g., a falling edge), the second tracking cell 140 can transition a control signal (e.g., the above-mentioned ASTE signal) present on the control line 160 to activate a WL assistance circuit (e.g., 104). The third tracking cells 145 enable the capacitive and resistive environment to be matched closely for accurate modeling of the environment for nominal memory cells. Nominal bit lines BLs that are tracked typically have two factors that determine propagation delay of signals that are carried, namely serial resistance and parallel capacitance. The third tracking cells 145 have real capacitive load, and mimic the capacitance of nominal bit lines BLs coupled to the nominal memory cells. In certain cases, if the third tracking cells 145 were not provided, the length of the tracking bit line would effectively appear to be shorter than the nominal bit lines BLs they are intended to emulate, which would decrease resistance and capacitance, and which might lead tracking circuitry to determine that read or write operations have concluded prematurely.

The memory controller 102 is a hardware component that is configured to control various operations of the memory array 120 such as, for example, reading data bits from the nominal memory cells 125, writing data bits into the nominal memory cells 125, performing a tracking scheme on respective timings of the read/write operation so as to activate a WL assistance circuit, etc. In various embodiments of the present disclosure, the WL assistance circuit (e.g., 104), upon being activated based on a tracking timing, can boost or otherwise increase the voltage level present on a nominal word line WL asserted (sometimes referred to as a WL voltage). With this accurately boosted WL voltage, performance (e.g., margins) of various operations performed on the nominal memory cells 125 can be significantly improved. Although not expressly shown, the memory controller 102 can include a number of circuits, each of which may be embodied as logic circuits, analog circuits, or a combination thereof, to perform such operations.

Similarly, each of the WL assistance circuit 104, WL driver 106, pre-charge circuit 108, and BL assistance circuit 110 is a hardware component embodied as logic circuits, analog circuits, or a combination of them, to perform a respective operation. For example, the WL assistance circuit 104 can selectively boost a supply voltage (e.g., VDD) based on the control signal (ASTE signal) provided by the second tracking cell 140. The WL driver 106 can apply a voltage (e.g., a WL voltage) on one or more nominal word lines WL of the memory array 120 being asserted. The WL driver 106 can receive such a WL voltage, which may be selectively boosted, from the WL assistance circuit 104. The pre-charge circuit 108 can pre-charge the bit lines BLs (including the nominal ones and tracking ones) outside normal (e.g., read or write) operation of the nominal memory cells 125. The pre-charge circuit 108 generally pre-charge the bit lines to the supply voltage (VDD). The optional BL assistance circuit 110, operatively coupled to the pre-charge circuit 108, can decrease a voltage level present on those pre-charged bit lines BLs, to further improve the performance of the memory circuit 100 (e.g., increasing speed of the write operation).

In some embodiments, the memory circuit 100 can further include an input/output (I/O) circuit 170. The I/O circuit 170 can sense a voltage or current conducted through one or more nominal bit lines BLs of the memory array 120. For example, the I/O circuit 170 may include a number of sense amplifiers. Each of the sense amplifiers is operatively coupled to one or more of the nominal bit lines BLs inside the memory array 120. Each of the sense amplifiers, once being activated, can amplify a latched input value, which may be a voltage sensed from a corresponding nominal memory cell 125 through its coupled nominal bit lines BL/BLB.

FIG. 2 illustrates an example circuit diagram of a portion of the memory circuit 100, in accordance with some embodiments. For example, in FIG. 2, circuit implementations of the memory array 120, the tracking column 130, the WL assistance circuit 104, and the WL driver 106 are partially shown, respectively. The circuit diagram shown in FIG. 2 has been simplified for illustrative purposes, and thus, it should be appreciated that the components of the memory circuit 100 can be implemented in various other way while remaining within the scope of the present disclosure.

As described above, each of the nominal memory cells 125 of the memory array 120 may be implemented as a 6T SRAM cell, which includes pass-gate transistors, PG1 and PG2, pull-up transistors, PU1 and PU2, and pull-down transistors, PD1 and PD2, and is coupled between a corresponding pair of nominal BL and BLB. In some embodiments of the present disclosure, each of the tracking cells of the tracking column 130, e.g., the first tracking cell 135, the second tracking cell 140, and the third tracking cell 145, may be similar to the nominal memory cell 125, with respective modification. Accordingly, the following discussion on the tracking cells 135 to 145 will be focused on the difference.

For example, the first tracking cell 135 includes six transistors, 201, 202, 203, 204, 205, and 206, which are similarly configured as PU1, PU2, PD1, PD2, PG1, and PG2 of the nominal memory cell 125, respectively. The transistor 201, while having its gate terminal connected to a gate terminal of the transistor 203 (both of which are connected to VDD), has its source terminal and drain terminal both floating; and the transistor 202, while having its gate terminal connected to a gate terminal of the transistor 204, has its source terminal connected to VDD and drain terminal floating. The transistor 205 has its gate terminal connected to the tracking word line TRKWL 150, drain terminal connected to the tracking bit line TRKBL 155, and source terminal coupled to a ground voltage (VSS) through the transistor 203; and the transistor 206 has its gate terminal connected to a corresponding nominal word line WL (e.g., WL[0]), drain terminal connected to another tracking bit line TRKBLB 157 which is a complement of the tracking bit line TRKBL 155, and source terminal coupled to the ground voltage through the transistor 204. With such a configuration, upon the tracking word line TRKWL 150 is asserted (e.g., the TRKWL signal being pulled up), the transistor 205 can be turned on to discharge the tracking bit line TRKBL 155 that emulates the nominal bit line BL.

In another example, the second tracking cell 140 includes six transistors, 211, 212, 213, 214, 215, and 216, which are similarly configured as PU1, PU2, PD1, PD2, PG1, and PG2 of the nominal memory cell 125, respectively. The transistor 211, while having its gate terminal connected to a gate terminal of the transistor 213, has its source terminal floating and drain terminal connected to a drain terminal of the transistor 213; and the transistor 212, while having its gate terminal connected to a gate terminal of the transistor 214, has its source terminal connected to VDD and drain terminal connected to a drain terminal of the transistor 214. A source terminal of the transistor 213 may also be floating. The transistor 215 has its gate terminal connected to the ground voltage (VSS), drain terminal connected to the tracking bit line TRKBL 155, and source terminal connected to a common node “X” between the transistors 211 and 213; and the transistor 216 has its gate terminal connected to a corresponding nominal word line WL (e.g., WL[J−1]), drain terminal connected to the control line 160, and source terminal connected to a common node “Y” between the transistors 212 and 214. Further, the second tracking cell 140 can include one or more first conductive lines directly connecting the tracking bit line TRKBL 155 to the node X, and one or more second conductive lines directly connecting the control line 160 to the node Y.

In some embodiments, the transistors 212 and 214 can operatively serve as an inverter with an input and an output, in which the input (e.g., the node X) is coupled to the tracking bit line TRKBL 155. As such, when the TRKBL signal present on the tracking bit line TRKBL 155 transitions (e.g., being pulled down by the first tracking cell 135), the output (e.g., the node Y) can transition accordingly (e.g., being pulled up). Consequently, the ASTE signal present on the control line 160 that is directly coupled to the node Y can transition (e.g., to a logic high state). According to various embodiments of the present disclosure, upon the ASTE signal being pulled up, the WL assistance circuit 104 can be activated to boost the supply voltage VDD, which will be described below.

In yet another example, the third tracking cell 145 includes six transistors, 221, 222, 223, 224, 225, and 226, which are similarly configured as PU1, PU2, PD1, PD2, PG1, and PG2 of the nominal memory cell 125, respectively. The transistor 221, while having its gate terminal connected to a gate terminal of the transistor 223 (both of which are connected to VDD), has its source terminal and drain terminal both floating; and the transistor 222, while having its gate terminal connected to a gate terminal of the transistor 224, has its source terminal and drain terminal both floating. The transistor 225 has its gate terminal connected to the ground voltage (VSS), drain terminal connected to the tracking bit line TRKBL 155, and source terminal coupled to a ground voltage through the transistor 223; and the transistor 226 has its gate terminal connected to a corresponding nominal word line WL (e.g., WL[J−2]), drain terminal connected to the tracking bit line TRKBLB 157, and source terminal coupled to the ground voltage through the transistor 224. With such a configuration, the third tracking cell 145 can emulate a loading of the nominal bit line BL.

The WL assistance circuit 104 can include buffers 230-232, a transistor 234, and a capacitor 236. The transistor 234 may be implemented as a PMOS transistor coupled between the supply voltage (VDD) and a first terminal of the capacitor 236. The first terminal of the capacitor 236 can be coupled to the WL driver 106. As shown in the example of FIG. 2, the WL driver 106 can include a plural number of WL buffers or WL inverters, 160[J−1], 160[J−2] . . . 160[0], coupled to the nominal word lines WL[J−1], WL[J−2] . . . WL[0], respectively. In some embodiments, the first terminal of the capacitor 236 is configured to provide an operation voltage (VDDHD) to power the WL inverters of the WL driver 106, such that each of the WL inverters can apply the operation voltage (VDDHD) to a corresponding one of the nominal word lines WL once being asserted. VDDHD can sometimes be referred to as a virtual supply voltage.

In some embodiments, the WL assistance circuit 104 can operate with two phases. Based on a logic state of the ASTE signal (present on the control line 160), one of the phases is configured to provide the VDDHD as VDD, and the other of the phases is configured to provide the VDDHD as VDD plus a boosted amount. For example, when the ASTE signal is a logic low state or VSS (e.g., with the TRKBL signal kept at a logic high state), the transistor 234 can be turned on, which couples VDD to the operation voltage (VDDHD). Since a second terminal of the capacitor 236 couped to the ASTE signal is held at VSS, a voltage difference across the first terminal and second terminal of the capacitor 236 is ΔV=VDD-VSS. When the ASTE signal transitions from the logic low state to a logic high state or VDD, the transistor 234 is turned off, which decouples VDD from the operation voltage (VDDHD). Accordingly, the capacitor 236 can boost a voltage level at its first terminal (i.e., the operation voltage VDDHD) to VDD+ΔV.

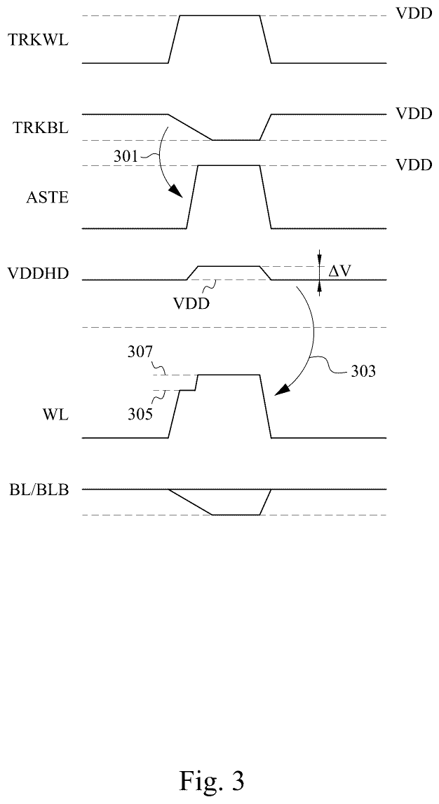

FIG. 3 illustrates waveforms of various signals over time when operating the memory circuit 100 implemented as the circuit diagram of FIG. 2, respectively, in accordance with some embodiments. For example, the waveforms of the TRKWL signal, the TRKBL signal, the ASTE signal, the VDDHD, the WL signal (voltage), and voltages present on the nominal bit lines BL/BLB are shown, respectively. In some embodiments, once the VDDHD is boosted from VDD, the WL voltage can be boosted or otherwise elevated from VDD accordingly. The boosted WL voltage can be advantageously utilized to improve performance of the nominal memory cell 125 while being read and/or written.

As shown in FIG. 3, when the TRKWL signal is pulled up (e.g., concurrently with the WL voltage being pulled up), the first tracking cell 135 can be activated to pull down the TRKBL signal. In some embodiments, the TRKWL signal can be provided by a tracking WL driver, which can be a part of the WL driver 106 or the memory controller 102. Upon the TRKBL signal being pulled down to a certain voltage level, which can be previously defined, the ASTE signal can be pulled up, as indicated by symbolic arrow 301. According to various embodiments of the present disclosure, the second tracking cell 140 can make such a transition of the ASTE signal upon detecting that the TRKBL signal is pulled down to a sufficiently low voltage level. Essentially, the second tracking cell 140 operatively serve as an inverter coupled between the TRKBL 155 (presenting the TRKBL signal) and the control line 160 (presenting the ASTE signal). When the ASTE signal is pulled up, the WL assistance circuit 104 can increase the VDDHD with an amount of ΔV (e.g., around VDD-VSS). For example, the VDDHD may be boosted from VDD to VDD+ΔV Accordingly (as indicated by symbolic arrow 303), the WL voltage, applied on an asserted nominal word line WL by the WL driver 106, can be boosted from a first level 305 to a second level 307.

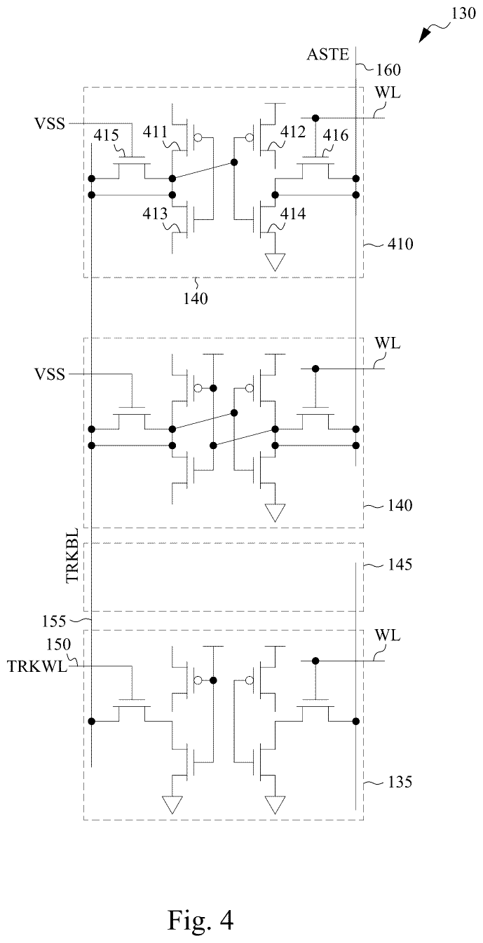

FIG. 4 illustrates a circuit diagram of another implementation of the tracking column 130, in accordance with some embodiments. The circuit implementation of the tracking column 130 shown in FIG. 4 is similar to that shown in FIG. 2, except that the tracking column 130 of FIG. 4 further includes another type of tracking cell.

As shown in FIG. 4, in addition to the tracking cells 135 to 145, the tracking column 130 includes a tracking cell 410. The tracking cell 410 also includes six transistors, 411, 412, 413, 414, 415, and 416, which are similarly configured as PU1, PU2, PD1, PD2, PG1, and PG2 of the nominal memory cell 125, respectively. The transistor 411, while having its gate terminal connected to a gate terminal of the transistor 413, has its source terminal floating and drain terminal connected to a drain terminal of the transistor 413; and the transistor 412, while having its gate terminal connected to a gate terminal of the transistor 414, has its source terminal connected to VDD and drain terminal disconnected from a drain terminal of the transistor 414. A source terminal of the transistor 413 may also be floating. The transistor 415 has its gate terminal connected to the ground voltage (VSS), drain terminal connected to the tracking bit line TRKBL 155, and source terminal connected to a common node “X” between the transistors 411 and 413; and the transistor 416 has its gate terminal connected to a corresponding nominal word line WL, drain terminal connected to the control line 160, and source terminal connected to the drain terminal of the transistor 414. Further, the tracking cell 410 can include one or more first conductive lines directly connecting the tracking bit line TRKBL 155 to the node X, and one or more second conductive lines directly connecting the control line 160 to the drain terminal of the transistor 414. With such a configuration, the tracking cell 410 can lower a threshold voltage of the second tracking cell 140, which can advantageously prevent the ASTE signal from being pulled up too early.

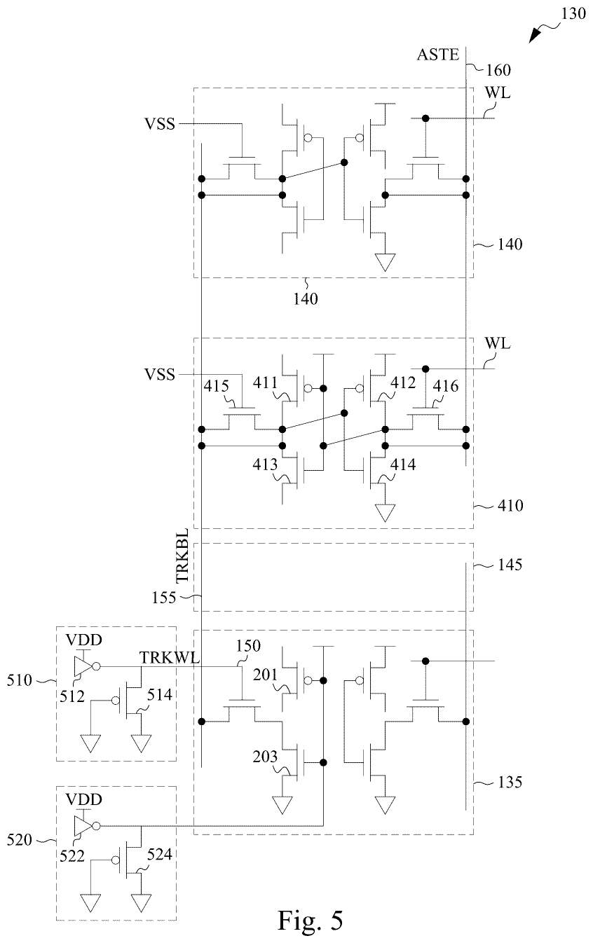

FIG. 5 illustrates a circuit diagram of another implementation of the tracking column 130, in accordance with some embodiments. The circuit implementation of the tracking column 130 shown in FIG. 5 is similar to that shown in FIG. 4, except that the tracking column 130 of FIG. 5 is further coupled to one or more level generators.

As shown in FIG. 5, the first tracking cell 135 is coupled to a level generator 510. The level generator 510 is configured to decrease a voltage level present on the tracking word line TRKWL 150. By decreasing the voltage level of the TRKWL, the tracking cell 135, activated by the TRKWL, can mimic one or more of the nominal memory cells 125 that are relatively weak (e.g., having its pull-up transistors with a relatively or abnormally low threshold voltage). In some embodiments, the level generator 510 can include an inverter 512 and a transistor 514. The inverter 512 may be powered by the supply voltage (VDD). The transistor 514 may be implemented as a PMOS transistor. Further, the transistor 514 has its gate terminal connected to the ground voltage (VSS), which always turns on the transistor 514, and source and drain terminals connected to the tracking word line TRKWL 150 and VSS, respectively. Accordingly, upon the tracking word line TRKWL 150 being asserted, the voltage level of the TRKWL can be dropped. In some other embodiments, the first tracking cell 135 can be further optionally coupled to another level generator 520, which also has an inverter 522 and a PMOS transistor 524. The level generator 520 may be coupled to the gate terminal of the pull-down transistor 203 of the first tracking cell 135.

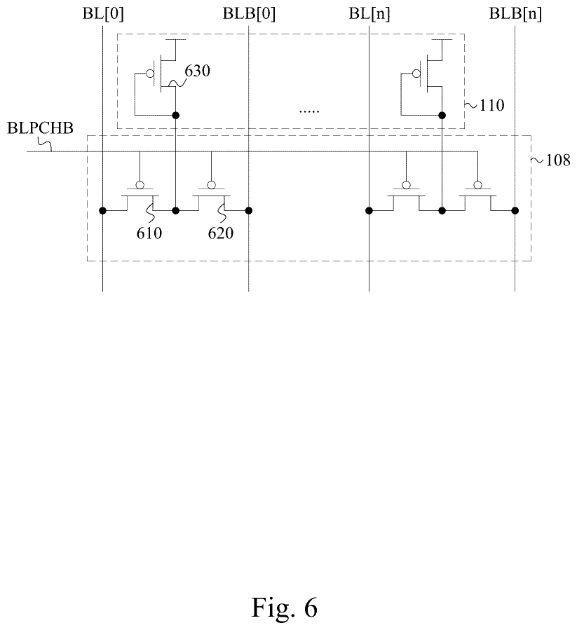

FIG. 6 illustrates an example circuit diagram of a portion of the memory circuit 100, in accordance with some embodiments. For example, in FIG. 6, circuit implementations of the pre-charge circuit 108 and the BL assistance circuit 110 are partially shown, respectively. The circuit diagram shown in FIG. 6 has been simplified for illustrative purposes, and thus, it should be appreciated that the components of the memory circuit 100 can be implemented in various other way while remaining within the scope of the present disclosure.

As shown in FIG. 6, the pre-charge circuit 108 includes a number of transistors 610 and 620, and the BL assistance circuit 110 includes a transistor 630, in which the transistors 610-620 of the pre-charge circuit 108 are coupled to a corresponding pair of the nominal bit lines BL/BLB (e.g., BL[0] and BLB[0]) and the transistor 630 of the BL assistance circuit 110 is coupled to a corresponding pair of the nominal bit lines BL/BLB (e.g., BL[0] and BLB[0]). In some embodiments, each of the transistors 610 to 630 may be implemented as a PMOS transistor. Specifically, respective gate terminals of the transistors 610 and 620 of the pre-charge circuit 108 are connected to each other and configured to receive a bit line pre-charge (BLPCHB) signal; respective first source/drain terminals of the transistors 610 and 620 of the pre-charge circuit 108 are connected to the nominal bit line BL and its complement bit line BLB; and respective second source/drain terminals of the transistors 610 and 620 of the pre-charge circuit 108 are connected to each other. The second source/drain terminals of the transistors 610 and 620 are connected to a drain terminal of the transistor 630 of the BL assistance circuit 110 that is further connected to a gate terminal of the transistor 630 of the BL assistance circuit 110. A source terminal of the transistor 630 of the BL assistance circuit 110 is connected to the supply voltage (VDD).

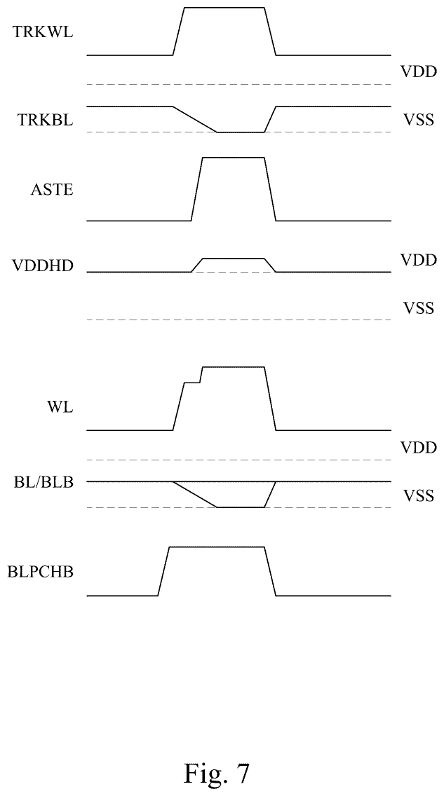

In some embodiments, the pre-charge circuit 108 is configured to pre-charge the nominal bit lines BL/BLB and the tracking bit lines TRKBL 155 to VDD, and the BL assistance circuit 110 is configured to lower a voltage level of that pre-charged voltage present on the nominal bit lines BL/BLB and the tracking bit lines TRKBL 155. For example, in FIG. 7, outside the normal operation (read or write) of the nominal memory cell 125 where the WL voltage remains at a logic low state, the BLPCHB signal is provided at the logic low state, which can activate the pre-charge circuit 108 to pre-charge the nominal bit lines BL/BLB and also the tracking bit lines TRKBL 155. Further, concurrently with the bit lines are pre-charged to VDD, the BL assistance circuit 110 can be activated to pull down the voltage level present on the bit lines from VDD, as illustrated in FIG. 7. By dropping the pre-charged voltage on the bit lines from VDD a bit, performance of the memory circuit 100 can be further improved (e.g., increasing speed of the write operation).

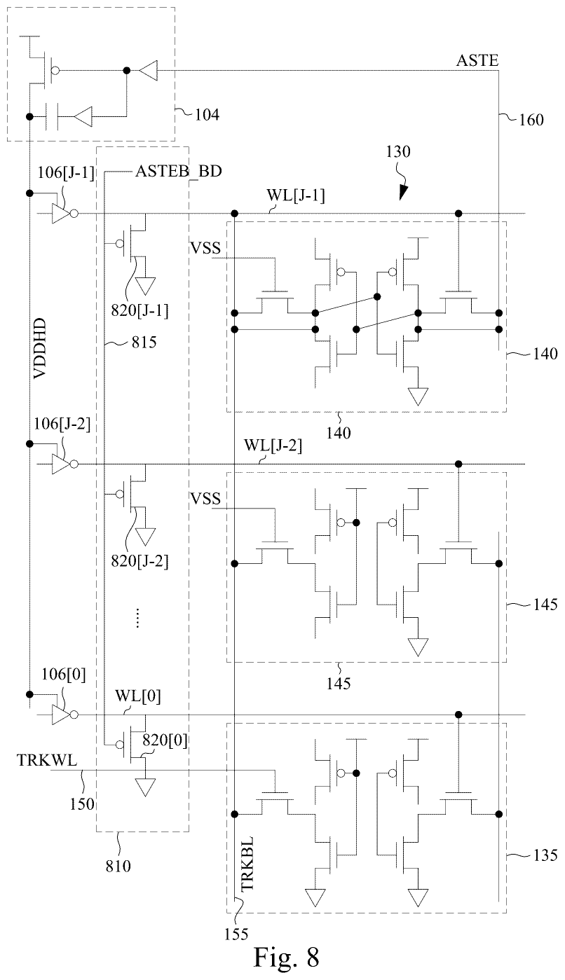

FIG. 8 illustrates another example circuit diagram of a portion of the memory circuit 100, in accordance with some embodiments. The circuit diagram of FIG. 8 is similar to that shown in FIG. 2, except that the circuit diagram of FIG. 8 further includes a WL suppression circuit 810. For example, in FIG. 8, together with the WL suppression circuit 810, circuit implementations of the memory array 120, the tracking column 130, the WL assistance circuit 104, and the WL driver 106 are partially shown, respectively. The circuit diagram shown in FIG. 8 has been simplified for illustrative purposes, and thus, it should be appreciated that the components of the memory circuit 100 can be implemented in various other way while remaining within the scope of the present disclosure.

As shown in FIG. 8, the WL suppression circuit 810 includes a number of transistors, 820[J−1], 820[J−2] . . . 820[0], coupled to the nominal word lines WL[J−1], WL[J−2] . . . WL[0], respectively. The transistors 820 may each be implemented as a PMOS transistor, in some embodiments. Specifically, source terminals of the transistors 820 can be connected to the nominal word lines WL, respectively; gate terminals of the transistors 820 can be commonly connected to another control line 815 (presenting or receiving an ASTEB_RD signal); and drain terminals of the transistors 820 can each be connected to the ground voltage (VSS).

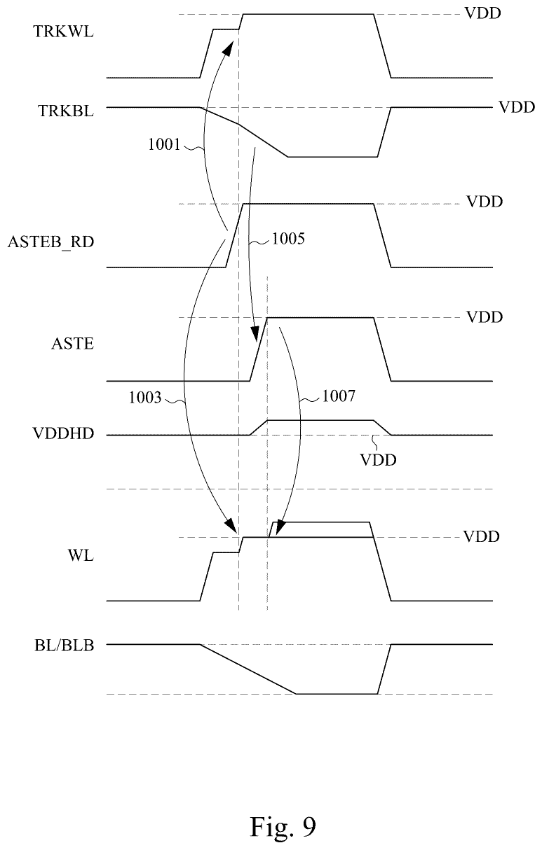

In such an embodiment, the memory circuit 100 can utilize the ASTEB_RD signal to suppress the voltage level present on the nominal word lines WL and on the tracking word line TRKWL 150. For example, prior to the ASTEB_RD signal transitioning from a low logic state to a high logic state, the voltage level present on the word lines (e.g., including WL[0] to WL[J−1] and TRKWL 150) may be lower than VDD, and upon the ASTEB_RD signal transitioning to the logic high state, the voltage level present on the word lines can be elevated to VDD. Accordingly, the memory circuit 100 can further include an ASTEB_RD driver 910 (FIG. 9) configured to provide the ASTEB_RS signal and a tracking WL driver 950 (FIG. 9) configured to provide the TRKWL signal based on the ASTEB_RD signal. Each of the ASTEB_RD driver 910 and the tracking WL driver 950 can be a part of the WL driver 106 or the memory controller 102.

Referring to FIG. 9, example circuit diagrams of the ASTEB_RD driver 910 and the tracking WL driver 950 are shown, respectively. The tracking WL driver 950 can include inverters 952 and 954, and a PMOS transistor 956. The inverters 952 and 954 can both receive a control signal 901 configured to activate or assert the tracking word line TRKWL 150. Further, the inverter 952 of the tracking WL driver 950 can provide the TRKWL signal at its output based on the received control signal 901, with the output coupled to the ground voltage through the PMOS transistor 956. The PMOS transistor 956 of the tracking WL driver 950 can be gated by the ASTEB_RD signal. The inverter 954 of the tracking WL driver 950 can provide an intermediate signal to the ASTEB_RD driver 910 based on the received control signal 901. The ASTEB_RD driver 910 can include inverters 912 and 914 connected to each other in series. The ASTEB_RD driver 910 can provide the ASTEB_RD signal through the inverters 912 and 914 based on the intermediate signal received from the inverter 954 of the tracking WL driver 950.

With such a configuration, the TRKWL signal can be suppressed from VDD when the ASTEB_RD signal is at the logic low state. For example, when the ASTEB_RD signal is at the logic low state, the PMOS transistor 956 of the tracking WL driver 950 can be turned on. The PMOS transistor 956 is generally formed with a relatively large resistance (when conducted), and thus, when the PMOS transistor 956 is turned on, the TRKWL signal can be pulled back from VDD with a voltage drop (ΔV). When the ASTEB_RD signal transitions from the logic low state to the logic high state, the PMOS transistor 956 is turned off, which disconnects the tracking word line TRKWL 150 from the ground voltage. Consequently, the TRKWL signal can be elevated to VDD. The WL voltage present on the nominal word lines WL can be controlled in similar fashion through the respective PMOS transistors 820 that are also gated by the ASTEB_RD signal.

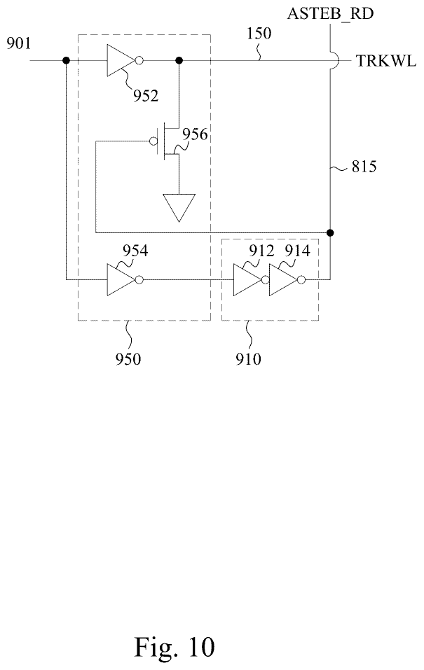

FIG. 10 illustrates waveforms of various signals over time when operating the memory circuit 100 implemented as the circuit diagram of FIG. 8, respectively, in accordance with some embodiments. For example, the waveforms of the TRKWL signal, the TRKBL signal, the ASTEB_RD signal, the ASTE signal, the VDDHD, the WL signal (voltage), and voltages present on the nominal bit lines BL/BLB are shown, respectively. In some embodiments, once the VDDHD is boosted from VDD, the WL voltage can be boosted or otherwise elevated from VDD accordingly. The boosted WL voltage can be advantageously utilized to improve performance of the nominal memory cell 125 while being read and/or written. Further, prior to reaching the VDD level, the TRKWL signal and the WL voltage may be suppressed under VDD based on the ASTEB_RD signal to further prevent data corruption.

As shown in FIG. 10, when the TRKWL signal is pulled up (e.g., concurrently with the WL voltage being pulled up), the first tracking cell 135 can be activated to pull down the TRKBL signal. In some embodiments, when the TRKWL signal and the WL voltage are initially pulled up, the ASTEB_RD signal may be kept at a logic low state. When the ASTEB_RD signal is at the logic low state, the TRKWL signal and the WL voltage are both suppressed from VDD. Upon the ASTEB_RD signal being transitioning to a logic high state, the TRKWL signal and the WL voltage can be pulled up to VDD, as indicated by symbolic arrows 1001 and 1003, respectively. Upon the TRKBL signal being pulled down to a certain voltage level, which can be previously defined, the ASTE signal can be pulled up, as indicated by symbolic arrow 1005. According to various embodiments of the present disclosure, the second tracking cell 140 can make such a transition of the ASTE signal upon detecting that the TRKBL signal is pulled down to a sufficiently low voltage level. When the ASTE signal is pulled up, the WL assistance circuit 104 can increase the VDDHD with an amount of ΔV (e.g., around VDD-VSS). For example, the VDDHD may be boosted from VDD to VDD+ΔV. Accordingly (as indicated by symbolic arrow 1007), the WL voltage, applied on an asserted nominal word line WL by the WL driver 106, can be boosted higher than VDD.

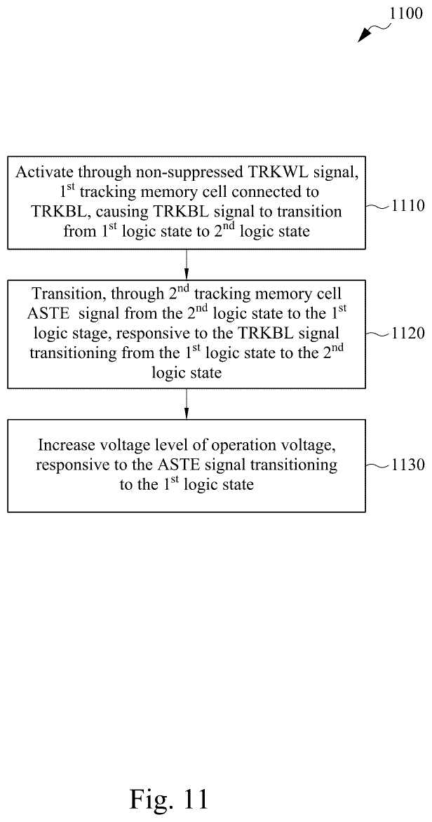

FIG. 11 illustrates a flow chart of an example method 1100 for operating a memory circuit including a WL assistance circuit controlled based on a tracking signal, in accordance with some embodiments. For example, operation of the method 1100 can be configured for operating the memory circuit 100 being implemented according to the circuit diagram shown in FIG. 2. Accordingly, the following discussion of the method 1100 may sometimes refer to the above figures. It should be noted that the method 1100 as shown in FIG. 11 is merely an example, and is not intended to limit the present disclosure. Thus, it is understood that the order of the operations of the method 1100 of FIG. 11 can be changed, for example, additional operations may be provided before, during, and after the method 1100, and that some operations may only be described briefly herein.

The method 1100 starts with operation 1110 of activating, through a non-suppressed tracking word line signal, a first tracking memory cell connected to a tracking bit line that mimics a propagation delay present on a nominal bit line, thereby causing a first signal present on the tracking bit line to transition from a first logic state to a second logic state. The first tracking memory cell can be activated by a tracking word line signal that can be asserted to VDD concurrently with asserting a nominal word line signal. For example, in FIG. 2, the first tracking memory cell 135 can be activated upon the TRKWL signal (present on the tracking word line TRKWL 150) being pulled up from a logic low state, which may correspond to VSS, to a logic high state, which may correspond to VDD. Upon being activated, the first tracking memory cell 135 can start to pull down the TRKBL signal (present on the tracking bit line TRKBL 155), which has been pre-charged to VDD (or suppressed VDD in some other embodiments, e.g., FIG. 6).

The method 1100 proceeds to operation 1120 of transitioning, through a second tracking memory cell connected to the tracking bit line, a second signal present on a control line from the second logic state to the first logic state, in response to the first signal transitioning from the first logic state to the second logic state. Continuing with the example of FIG. 2, the second tracking memory cell 140 can detect or otherwise monitor the TRKBL signal. Once the TRKBL signal transitions form the logic high state (e.g., the pre-charged VDD) to the logic low state, the second tracking memory cell 140 can pull up the ASTE signal (present on the control line 160).

In some embodiments, the second tracking memory cell 140 includes a first PMOS transistor (e.g., 211) and a first NMOS transistor (e.g., 213) connected to each other in series at a first node (e.g., node X), where a source terminal of the first PMOS transistor 211 being floating and a source terminal of the first NMOS transistor 213 being floating. The second tracking memory cell 140 further includes a second PMOS transistor (e.g., 212) and a second NMOS transistor (e.g., 214) connected to each other in series at a second node (e.g., node Y), a source terminal of the second PMOS transistor 212 connected to a supply voltage (VDD) and a source terminal of the second NMOS transistor 214 connected to a ground voltage (VSS). The second tracking memory cell 140 further includes a first pass-gate NMOS transistor (e.g., 215) having its source/drain terminals connected to the tracking bit line TRKBL 155 and the node X, respectively. The second tracking memory cell 140 further includes a second NMOS pass-gate transistor (e.g., 216) having its source/drain terminals connected to the control line 160 and the node Y, respectively. Further, the second tracking memory cell 140 further includes at least one conductive line directly connecting the tracking bit line TRKBL 155 to the node X, and another conductive line directly connecting the control line 160 to the node Y.

The method 1100 proceeds to operation 1130 of increasing a voltage level of an operation voltage applied to a nominal word line corresponding to an asserted one of a plurality of nominal memory cells, in response to the second signal transitioning to the first logic state. Continuing with the example of FIG. 2, once the ASTE signal is pulled up to the logic high state, the WL assistance circuit 104 is activated. Upon being activated, the WL assistance circuit 104 can elevate the operation voltage (VDDHD) from VDD to VDD+ΔV. Such an operation voltage can be configured to power the WL driver 106, which causes the WL voltage (present on the nominal word lines WL) to be elevated to VDD+ΔV, in some embodiments.

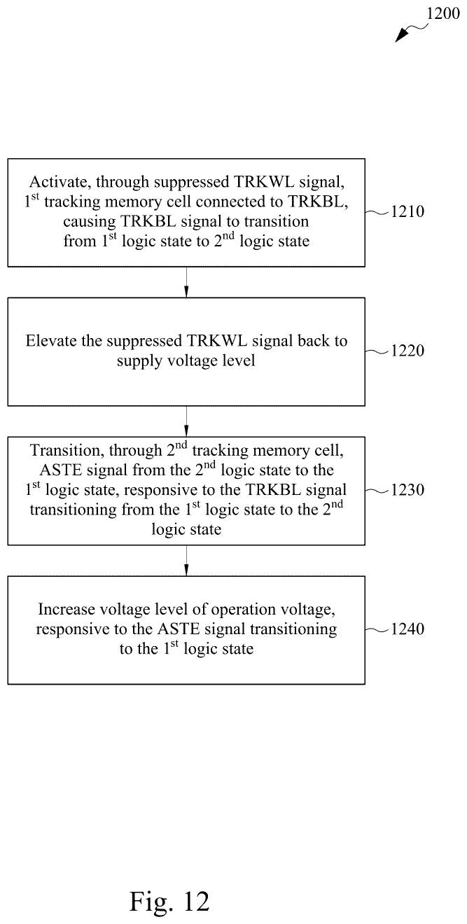

FIG. 12 illustrates a flow chart of an example method 1200 for operating a memory circuit including a WL assistance circuit controlled based on a tracking signal, in accordance with some embodiments. For example, operation of the method 1200 can be configured for operating the memory circuit 100 being implemented according to the circuit diagram shown in FIG. 8. Accordingly, the following discussion of the method 1200 may sometimes refer to the above figures. It should be noted that the method 1200 as shown in FIG. 12 is merely an example, and is not intended to limit the present disclosure. Thus, it is understood that the order of the operations of the method 1200 of FIG. 12 can be changed, for example, additional operations may be provided before, during, and after the method 1200, and that some operations may only be described briefly herein.

The method 1200 starts with operation 1210 of activating, through a suppressed tracking word line signal, a first tracking memory cell connected to a tracking bit line that mimics a propagation delay present on a nominal bit line, thereby causing a first signal present on the tracking bit line to transition from a first logic state to a second logic state. The first tracking memory cell can be activated by a tracking word line signal that can be asserted to suppressed VDD concurrently with asserting a nominal word line signal. In some embodiments, the tracking word line signal may remain at the level of suppressed VDD when another control signal remains at the second logic state. For example, in FIG. 8, the first tracking memory cell 135 can be activated upon the TRKWL signal (present on the tracking word line TRKWL 150) being pulled up from a logic low state, which may correspond to VSS, to a logic high state, which may correspond to that suppressed VDD. As long as the ASTEB_RD signal is held at the logic low state, the TRKWL signal and the WL voltage may maintain at the suppressed VDD level. Upon being activated, the first tracking memory cell 135 can start to pull down the TRKBL signal (present on the tracking bit line TRKBL 155), which has been pre-charged to VDD (or suppressed VDD in some alternative embodiments, e.g., FIG. 6).

The method 1200 proceeds to operation 1220 of elevating the suppressed tracking word line signal back to a supply voltage level. Continuing with the example of FIG. 8, once the ASTEB_RD signal transitions from the logic low state to the logic high state, the TRKWL signal (present on the tracking word line TRKWL 150) can be elevated back to VDD from the suppressed VDD. Concurrently, the WL voltage (present on the nominal word lines WL) can also be elevated from the suppressed to VDD. In some embodiments, the ASTEB_RD signal can be provided by the ASTEB_RD driver 910 based on the control signal 901 (FIG. 9).

The method 1200 proceeds to operation 1230 of transitioning, through a second tracking memory cell connected to the tracking bit line, a second signal present on a control line from the second logic state to the first logic state, in response to the first signal transitioning from the first logic state to the second logic state. Continuing with the example of FIG. 8, the second tracking memory cell 140 can detect or otherwise monitor the TRKBL signal. Once the TRKBL signal transitions form the logic high state (e.g., the pre-charged VDD) to the logic low state, the second tracking memory cell 140 can pull up the ASTE signal (present on the control line 160).

In some embodiments, the second tracking memory cell 140 includes a first PMOS transistor (e.g., 211) and a first NMOS transistor (e.g., 213) connected to each other in series at a first node (e.g., node X), where a source terminal of the first PMOS transistor 211 being floating and a source terminal of the first NMOS transistor 213 being floating. The second tracking memory cell 140 further includes a second PMOS transistor (e.g., 212) and a second NMOS transistor (e.g., 214) connected to each other in series at a second node (e.g., node Y), a source terminal of the second PMOS transistor 212 connected to a supply voltage (VDD) and a source terminal of the second NMOS transistor 214 connected to a ground voltage (VSS). The second tracking memory cell 140 further includes a first pass-gate NMOS transistor (e.g., 215) having its source/drain terminals connected to the tracking bit line TRKBL 155 and the node X, respectively. The second tracking memory cell 140 further includes a second NMOS pass-gate transistor (e.g., 216) having its source/drain terminals connected to the control line 160 and the node Y, respectively. Further, the second tracking memory cell 140 further includes at least one conductive line directly connecting the tracking bit line TRKBL 155 to the node X, and another conductive line directly connecting the control line 160 to the node Y.

The method 1200 proceeds to operation 1240 of increasing a voltage level of an operation voltage applied to a nominal word line corresponding to an asserted one of a plurality of nominal memory cells, in response to the second signal transitioning to the first logic state. Continuing with the example of FIG. 8, once the ASTE signal is pulled up to the logic high state, the WL assistance circuit 104 is activated. Upon being activated, the WL assistance circuit 104 can elevate the operation voltage (VDDHD) from VDD to VDD+ΔV. Such an operation voltage can be configured to power the WL driver 106, which causes the WL voltage (present on the nominal word lines WL) to be elevated from VDD to VDD+ΔV, in some embodiments.

In some other embodiments of the present disclosure, the transition direction of the various signal mentioned above can be reversed by adding an odd number of inverse logic gates (e.g., an inverter) or utilizing an opposite conductive type of transistors. For example, when a signal is asserted, the signal that gates a PMOS transistor may transition to a logic low state. Similarly, when a signal is negated, the signal that gates a PMOS transistor may transition to a logic high state.

In one aspect of the present disclosure, a memory circuit is disclosed. The memory circuit includes a memory array comprising a plurality of first memory cells, each of the plurality of first memory cells configured to store a data bit; a tracking column comprising at least a second memory cell and a third memory cell, wherein the second memory cell is coupled to a first tracking bit line, a second tracking bit line, and a tracking word line, and the third memory cell is coupled to the first tracking bit line; and a word line assistance circuit operatively coupled to the memory array and the tracking column. The word line assistance circuit is configured to receive a control signal present on a control line coupled to the third memory cell; and in response to the control signal being transitioning from a first logic state to a second logic state, increase a voltage level of an operation voltage applied to a word line corresponding to an asserted one of the plurality of first memory cells.

In another aspect of the present disclosure, a memory circuit is disclosed. The memory circuit includes a tracking column disposed next to a memory array comprising a plurality of first memory cells, each of the first memory cells configured to store a data bit, the tracking column comprising a plurality of second memory cells and a plurality of third memory cells. When activated through a tracking word line, each of the plurality of second memory cells is configured to pull down a first signal present on a first tracking bit line. Each of the plurality of third memory cells is configured to pull up a second signal present on a control line, in response to the first signal being pulled down.

In yet another aspect of the present disclosure, a method for operating memory circuits is disclosed. The method includes activating a first tracking memory cell connected to a tracking bit line that mimics a propagation delay present on a nominal bit line, thereby causing a first signal present on the tracking bit line to transition from a first logic state to a second logic state. The method includes transitioning, through a second tracking memory cell connected to the tracking bit line, a second signal present on a control line from the second logic state to the first logic state, in response to the first signal transitioning from the first logic state to the second logic state. The method includes increasing a voltage level of an operation voltage applied to a nominal word line corresponding to an asserted one of a plurality of nominal memory cells, in response to the second signal transitioning to the first logic state.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, +20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory circuit, comprising:
a memory array comprising a plurality of first memory cells, each of the plurality of first memory cells configured to store a data bit;
a tracking column comprising at least a second memory cell and a third memory cell, wherein the second memory cell is coupled to a first tracking bit line, a second tracking bit line, and a tracking word line, and the third memory cell is coupled to the first tracking bit line; and
a word line assistance circuit operatively coupled to the memory array and the tracking column, and configured to:
receive a control signal present on a control line coupled to the third memory cell; and
in response to the control signal being transitioning from a first logic state to a second logic state, increase a voltage level of an operation voltage applied to a word line corresponding to an asserted one of the plurality of first memory cells.

2. The memory circuit of claim 1, wherein the third memory cell comprises:
a first inverter and a second inverter cross-coupled to each other, forming a first node and a second node;
a first pass-gate transistor coupled between the first tracking bit line and the first node; and
a second pass-gate transistor coupled between the control line and the second node.

3. The memory circuit of claim 2, wherein the first node and the first tracking bit line are directly coupled to each other, and the second node and the control line are directly coupled to each other.

4. The memory circuit of claim 1, wherein, when activated through the tracking word line, the second memory cell is configured to transition a first signal present on the first tracking bit line from the second logic state to the first logic state.

5. The memory circuit of claim 4, wherein the third memory cell is configured to transition the control signal from the first logic state to the second logic state, in response to the first signal transitioning from the second logic state to the first logic state.

6. The memory circuit of claim 1, wherein the word line assistance circuit comprises:
a transistor having a gate terminal connected to the control line, a first source/drain terminal connected to a supply voltage, and a second source/drain terminal configured to provide the operation voltage; and
a capacitor having a first terminal and a second terminal connected to the control line and the second source/drain terminal, respectively.

7. The memory circuit of claim 6, wherein when the control signal is at the first logic state, the supply voltage is directly applied on the word line, and when the control signal transitions from the first logic state to the second logic state, the supply voltage applied on the word line is increased with a delta voltage through the capacitor.

8. The memory circuit of claim 1, wherein the tracking column further comprises a fourth memory cell coupled to the control line and the first tracking bit line.

9. The memory circuit of claim 8,
wherein the third memory cell comprises:
a first p-type transistor and a first n-type transistor connected to each other in series at a first node, a source terminal of the first p-type transistor being floating and a source terminal of the first n-type transistor being floating;
a second p-type transistor and a second n-type transistor connected to each other in series at a second node, a source terminal of the second p-type transistor connected to the supply voltage and a source terminal of the second n-type transistor connected to a ground voltage;
a first pass-gate transistor having its source/drain terminals connected to the first tracking bit line and the first node, respectively; and
a second pass-gate transistor having its source/drain terminals connected to the control line and the second node, respectively;
wherein the fourth memory cell comprises:
a third p-type transistor and a third n-type transistor connected to each other in series at a third node, a source terminal of the third p-type transistor being floating and a source terminal of the third n-type transistor being floating;
a fourth p-type transistor and a fourth n-type transistor, a source terminal of the fourth p-type transistor connected to the supply voltage and a source terminal of the fourth n-type transistor connected to a ground voltage;
a third pass-gate transistor having its source/drain terminals connected to the first tracking bit line and the third node, respectively; and
a fourth pass-gate transistor having its source/drain terminals connected to the control line and a drain terminal of the fourth n-type transistor, respectively.

10. The memory circuit of claim 9, wherein the tracking column comprises a plurality of the third memory cells and a plurality of the fourth memory cells.

11. The memory circuit of claim 1, further comprising at least one level generator coupled to the tracking word line and configured to decrease a second signal present on the tracking word line with a delta voltage.

12. A memory circuit, comprising:
a tracking column disposed next to a memory array comprising a plurality of first memory cells, each of the first memory cells configured to store a data bit, the tracking column comprising a plurality of second memory cells and a plurality of third memory cells;
wherein when activated through a tracking word line, each of the plurality of second memory cells is configured to pull down a first signal present on a first tracking bit line; and
wherein each of the plurality of third memory cells is configured to pull up a second signal present on a control line, in response to the first signal being pulled down.

13. The memory circuit of claim 12, wherein the second memory cell comprises:
a first p-type transistor and a first n-type transistor with their gate terminals connected to each other, a source terminal of the first p-type transistor being floating and a drain terminal of the first p-type transistor being floating;
a second p-type transistor and a second n-type transistor with their gate terminals connected to each other, a source terminal of the second p-type transistor connected to a supply voltage and a drain terminal of the second p-type transistor being floating;
a first pass-gate transistor having its source/drain terminals connected to the first tracking bit line and a drain terminal of the first n-type transistor, respectively; and
a second pass-gate transistor having its source/drain terminals connected to a second tracking bit line and a drain terminal of the second n-type transistor, respectively.

14. The memory circuit of claim 13, wherein the third memory cell comprises:
a third p-type transistor and a third n-type transistor connected to each other in series at a first node, a source terminal of the third p-type transistor being floating and a source terminal of the third n-type transistor being floating;
a fourth p-type transistor and a fourth n-type transistor connected to each other in series at a second node, a source terminal of the fourth p-type transistor connected to the supply voltage and a source terminal of the fourth n-type transistor connected to a ground voltage;
a third pass-gate transistor having its source/drain terminals connected to the first tracking bit line and the first node, respectively; and
a fourth pass-gate transistor having its source/drain terminals connected to the control line and the second node, respectively.

15. The memory circuit of claim 14, wherein the first node and the first tracking bit line are directly coupled to each other, and the second node and the control line are directly coupled to each other.

16. The memory circuit of claim 12, further comprising a word line assistance circuit configured to increase a voltage level of an operation voltage applied on a word line corresponding to an asserted one of the plurality of first memory cells, in response to the second signal being pulled up.

17. The memory circuit of claim 16, wherein the word line assistance circuit comprises:
a transistor having a gate terminal connected to the control line, a first source/drain terminal connected to the supply voltage, and a second source/drain terminal configured to provide the operation voltage; and
a capacitor having a first terminal and a second terminal connected to the control line and the second source/drain terminal, respectively.

18. The memory circuit of claim 17, wherein when the second signal is at the first logic state, the supply voltage is directly applied on the word line, and when the second signal transitions from the first logic state to the second logic state, the supply voltage applied on the word line is increased with a delta voltage through the capacitor.

19. A method for operating a memory circuit, comprising:
activating a first tracking memory cell connected to a tracking bit line that mimics a propagation delay present on a nominal bit line, thereby causing a first signal present on the tracking bit line to transition from a first logic state to a second logic state;
transitioning, through a second tracking memory cell connected to the tracking bit line, a second signal present on a control line from the second logic state to the first logic state, in response to the first signal transitioning from the first logic state to the second logic state; and
increasing a voltage level of an operation voltage applied to a nominal word line corresponding to an asserted one of a plurality of nominal memory cells, in response to the second signal transitioning to the first logic state.

20. The method of claim 19, wherein the second memory cell comprises:
a first p-type transistor and a first n-type transistor connected to each other in series at a first node, a source terminal of the first p-type transistor being floating and a source terminal of the first n-type transistor being floating;
a second p-type transistor and a second n-type transistor connected to each other in series at a second node, a source terminal of the second p-type transistor connected to a supply voltage and a source terminal of the second n-type transistor connected to a ground voltage;
a first pass-gate transistor having its source/drain terminals connected to the tracking bit line and the first node, respectively; and
a second pass-gate transistor having its source/drain terminals connected to the control line and the second node, respectively.
